(19) United States
(12) Patent Application Publication
(10) Pub. No.: US 2012/0062035 A1
(43) Pub. Date: Mar. 15, 2012

(54) Photovoltaic Device And Manufacturing Method

(76) Inventors: Bruno Estibals, Saint Thomas (FR); Corinne Alonso, Ramonville Saint Agne (FR); Marc Vermeersch, Le Vesinet (FR); Loic Francke, Nanterre (FR)

(21) Appl. No.: 13/319,559

(22) PCT Filed: May 11, 2010
(86) PCT No.: PCT/IB2010/052090

§ 371 Date: Nov. 9, 2011

(30) Foreign Application Priority Data
May 15, 2009 (FR) 0902354

(51) Int. Cl. G05F 1/67; H02M 7/44; H01L 31/02; H02M 3/04

(52) U.S. Cl. 307/71; 363/13; 363/65; 438/80; 257/E31.11

(57) ABSTRACT

The invention relates to a photovoltaic device comprising at least one photovoltaic cell (60) provided with active thin layers (15) deposited on a substrate (10), said active layers being unsegmented, and at least one static converter (50) associated with each photovoltaic cell (60). Each photovoltaic cell (60) supplies an electrical power with a maximum current (I_{cc}) and a nominal voltage (Vₚ), and each static converter (50) is adapted in such a way as to transmit the electrical power supplied by the photovoltaic cell towards a load (100), reducing the transmitted current and increasing the transmitted voltage. The laser segmentations of the photovoltaic cells are thus limited, or completely eliminated, on a same panel. The yield of the photovoltaic device production is thereby improved and the dead surfaces are limited.

The present invention relates to the field of photovoltaic devices and more particularly devices comprising photovoltaic cells produced in what is called thin-film technology. The invention also relates to the manufacture of a thin-film photovoltaic device.

As is known per se, a photovoltaic device comprises one or more photovoltaic (PV) cells connected in series and/or in parallel. In the case of inorganic materials, a photovoltaic cell essentially consists of a diode (p-n or p-i-n junction) made from a semiconductor material. This material has the property of absorbing light energy, a substantial part of which may be transferred to charge carriers (electrons and holes). Forming a diode (p-n or p-i-n junction), by respectively doping two regions n-type and p-type, optionally separated by an undoped region (called an “intrinsic” region and denoted by “i” in the expression p-i-n junction), enables separation and then collection of the charge carriers via electrodes provided with the photovoltaic cell. The potential difference (open-circuit voltage, V_{oc}) and maximum current (short-circuit current, I_{sc}) that the photovoltaic cell can supply depend both on the materials used to form the cell assembly and the environmental conditions which this cell is exposed to (including spectral intensity of the illumination, temperature, etc.). In the case of organic materials, the models are substantially different, making more use of the notion of donor and acceptor materials in which electron-hole pairs called excitons, are created. The end result remains the same: separation of charge carriers so as to collect and generate a current.

There are a number of known technologies for manufacturing photovoltaic cells. So called thin-film technologies were developed from an industrial standpoint from 1975 onwards; these technologies consist in depositing various materials as thin films on a substrate by PVD (physical vapor deposition) or PECVD (plasma-enhanced chemical vapor deposition). Other manufacturing technologies appeared later on, such as what is called crystalline-silicon technology, which at the current time represents most industrial production. These technologies consist in producing ingots of single-crystal or polycrystalline silicon and then cutting the ingots into wafers and doping the wafer in order to produce a p-n or p-i-n junction. Emerging technologies use organic cells or composite materials.

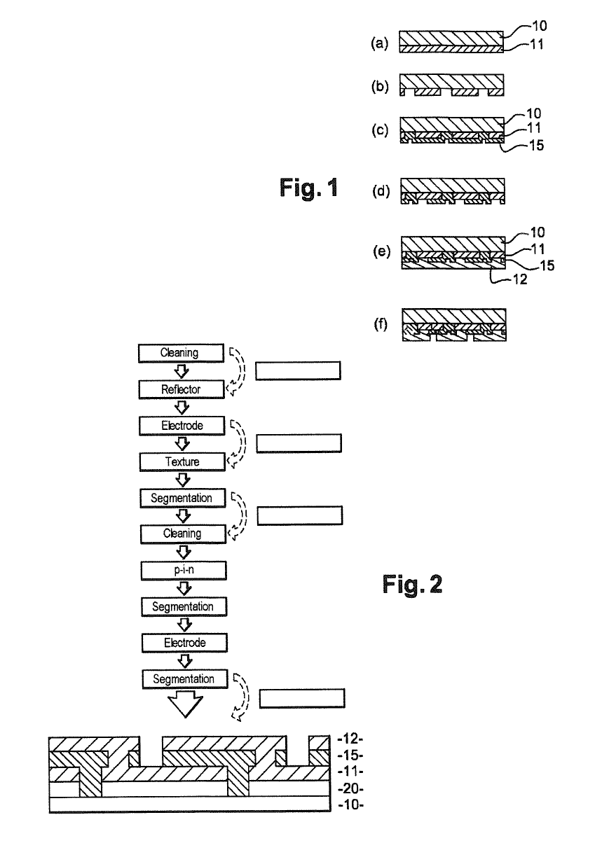

Thin-film photovoltaic cell technologies have many advantages. They enable high-throughput manufacturing processes for large areas compared to crystalline-silicon technologies. Thin-film photovoltaic cells also have a good energy efficiency when they are assembled into a module. The expression “photovoltaic module” is understood to mean an assembly of a plurality of photovoltaic cells. The module may furthermore be associated with control electronics typically comprising a static converter (SC) and optionally a maximum power point tracker (MPPT). FIG. 1 shows the steps of a conventional method for manufacturing a thin-film photovoltaic cell device. The thicknesses of the various films are not shown to scale in the diagram of FIG. 1.

In thin-film technologies, the various materials are deposited as thin films on a substrate 10 by PVD (physical vapor deposition) or by PECVD (plasma enhanced chemical vapor deposition) or even by sputtering or LPCVD (low-pressure chemical vapor deposition). In this way, a first conductive electrode 11, so called active films 15 forming one or more junctions, and a second conductive electrode 12 are deposited in succession. The electrodes 11, 12 are intended to collect the current produced by the active films 15. In thin-film technologies, sequencing steps are necessary to form a plurality of photovoltaic cells on a given substrate. Specifically, in order to increase manufacturing yield, the aim is to produce several cells on a given substrate by carrying out successive depositions over a large area, typically tens to several hundred cells are produced on a sheet measuring a few cm² at the research stage to more than 1 m² at the production stage, these cells then being connected in series so as to increase the output voltage of the device. The electrical analogy of a photovoltaic-cell device will be described in greater detail below with reference to FIGS. 4 to 6.

FIG. 1 shows a first step (a) in which a first electrode 11 is deposited on a substrate 10. The term “substrate” 10 is understood to mean the part that supports the active elements of the photovoltaic cell. The substrate may be rigid i.e. made of a pane of glass, or flexible i.e. made of a sheet of polymer or stainless steel or titanium; it may be transparent or opaque depending on whether or not it will be placed in the path of the incident light, relative to the active films. It is also possible for the substrate to be chosen to form at least one of the sheets encapsulating the final product, for example a glass substrate in the case of a rigid photovoltaic module. A person skilled in the art will be able to choose the substrate (glass, polymer or metal substrate) most suited to deposition of the various active films of the device to be manufactured.

The first electrode 11 may be made of an oxide film that is transparent to light, such as indium tin oxide (ITO), or of transparent conductive oxides (TCOs) such as indium oxide (In₂O₃), aluminum-doped zinc oxide (ZnO) or fluorine-doped tin oxide (SnO₂), for example. It is possible to plan to deposit a back reflective film directly on the substrate 10 before the first electrode (referenced 20 in FIG. 2), especially when the substrate 10 is transparent and the incident light penetrates the cell via the face opposite the substrate. The back reflective film may be a film made of copper, silver or aluminum, for example.

FIG. 1 shows a second step (b) in which the first electrode layer 11 is segmented so as to define strips that will form a corresponding number of individual diodes in a given panel bounded by the substrate 10; the area of the electrodes defines the maximum current that can be delivered by the diode constructed in this way. The segmentation is typically carried out by laser etching, for example with an Nd:YAG (neodymium-doped yttrium aluminum garnet) laser.

FIG. 1 shows a third step (c) in which the active films 15 are deposited. For example, thin films of hydrogenated amorphous silicon (a-Si:H), polymorphous silicon (pm-Si:H) or microcrystalline silicon (μc-Si:H) may be deposited so as to form one or more superposed p-n or p-i-n junctions. A person skilled in the art will be able to choose any material suitable for fabricating a p-n or p-i-n junction depending on the industrial equipment available and/or the required photoelectric efficiency. The active films 15 fill the gaps between the strips of the first electrode 11, thus isolating each electrode segment.

FIG. 1 shows a fourth step (d) in which the active films 15 are segmented until the first electrode 11 is exposed. The segmentation of the active films 15 is shifted relative to the segmentation of the first electrode 11 so that the second electrode, which will be deposited in step (e), and the first electrode 11 can make contact—thus ensuring that the diodes formed by adjacent strips are connected in series. As will be described below, connecting the diodes of a given panel in series allows a higher voltage, equal to the sum of the elementary voltages of each diode connected in series, to be obtained. The segmentation of the active films 15 is typically carried out by laser etching, for example with an Nd:YAG laser.

FIG. 1 shows a fifth step (e) in which a second electrode 12 is deposited so as to enclose, with the first electrode 11, the active films 15 of the cell. The second electrode 12 may have the same composition as the first electrode 11 or a different composition; it may consist of indium tin oxide (ITO) or any transparent conductive oxide (TCO), for example. The second electrode 12 may even be covered with a back reflector if the incident light penetrates the cell via the substrate 10; the second electrode 12 may also serve as a back reflector if it has a suitable composition, for example if it is made of an alloy of ITO, silver and nickel. The second electrode 12 fills the segmentation gaps of the active films 15, ensuring that adjacent strips are connected in series.

FIG. 1 lastly shows a sixth step (f) in which the second electrode 12 is segmented, until the active layers are exposed. The segmentation of the second electrode 12 is also shifted relative to the segmentation of the active films 15 and relative to the segmentation of the first electrode 11 so as to define, with the first segmentation of step (b), the active regions of the strips of individual diodes. The segmentation of the second electrode 12 is typically carried out by laser etching, for example with an Nd:YAG laser, or by mechanical etching.

FIG. 2 summarizes in a flow chart the manufacturing steps described with reference to FIG. 1. The substrate 10 is firstly cleaned and tested to check that there are no cracks or dust or defects on the surface of the substrate or even to check that the substrate is quite simply not broken. A reflector 20 may then be deposited; then the first electrode 11. The first electrode 11 is then given a texture, for example by annealing to give the deposited molecules the same crystal orientation, and segmented. The quality of the segmentation—width, sidewall angle, depth, etc.—is checked, and the substrate must be cleaned once more so as to remove metal residues resulting from the etching. The active films 15—whether forming p-i-n junctions or other junctions—are deposited and segmented, then the second electrode 12 is deposited and segmented. A final check is then carried out.

There are other methods for manufacturing thin-film photovoltaic cell devices with a different order to that described with reference to FIGS. 1 and 2. For example, the active films and the first electrode film may be segmented together and an insulating ink may be screen-printed. Next the second electrode is deposited and segmented. Finally a contact grid, made of silver for example, is screen-printed onto the second electrode and a reflow step of the grid is used to ensure that two adjacent photovoltaic strips are connected in series. A laser is used to reflow the metal film.

There are therefore typically three laser segmentation steps in a conventional method for manufacturing a thin-film photovoltaic cell device, whatever the method implemented and the nature or thickness of the deposited films. Each segmentation step must be carried out with a different laser, i.e. with different settings in terms of wavelength, resolution and angle of attack, in order to segment the required film or films. These segmentation steps represent a high cost for the method of manufacturing a thin-film photovoltaic cell device and are factors limiting production capacity. In addition, these segmentation steps are delicate and reduce production yield because they are responsible for many defects that lead to scrappage of entire devices.

Furthermore, segmentation reduces the useful area of the device. This is because all the regions that are destroyed by a segmentation groove cannot be used to produce photovoltaic energy. The active region of a photovoltaic cell is bounded by the first and third segmentation grooves. Thus, for example, for strips 12 mm in width, about 5 to 6% of the area, and therefore of the current delivered by the cell, is lost due to segmentation.

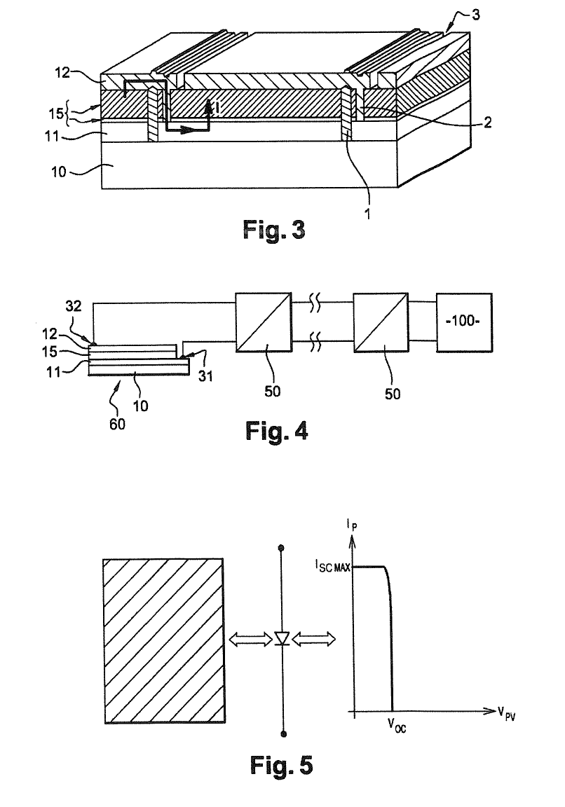

FIG. 3 shows a schematic cross-sectional view of part of a thin-film photovoltaic device with adjacent photovoltaic cells interconnected in series. The dimensions of the various films and segmentation grooves are not shown to scale in FIG. 3. FIG. 3 shows the substrate 10, the first electrode 11, the active photovoltaic films 15 and the second electrode 12.

FIG. 3 also shows a first segmentation groove 1 enabling electrical isolation of two adjacent photovoltaic cells; this first groove 1 is dug into the first electrode 11 and the active films 15 and filled with insulating ink. A second segmentation groove 2 is dug into the active films 15 and filled with the material of the second electrode 12 during deposition of the latter. A third segmentation groove 3 segments the second electrode 12 into strips. It may be seen in FIG. 3 (bold arrow) that the current I of a photovoltaic cell flows to the following cell through the second electrode, the second groove and the first electrode. Each photovoltaic cell, bounded by the first and third grooves 1, 3, is thus connected in series with the adjacent cell by means of the second groove 2.

Series connection of the cells of a photovoltaic device is required to increase the output voltage of the device to voltage levels compatible with external DC or AC loads to which the device is intended to be connected.

Segmentation of the thin films of a photovoltaic device is however a costly step, both in terms of time and hardware, and which step reduces the useful area of the device.

There is therefore a need for a method for manufacturing a thin-film photovoltaic device which enables increased manufacturing yield and which limits the dead area of the device.

For this purpose, the invention proposes to limit or even remove the laser segmentation step in the method for manufacturing a thin-film photovoltaic device; instead, one or a few large cells occupy the entire area of the device and supply a high current but at a limited voltage. At least one static converter is placed across the terminals of each cell in order to decrease the current and proportionally increase the voltage. It is thus possible, by adding suitable conversion electronics, to remove a restrictive step of the method for manufacturing the photovoltaic device.

The invention more specifically relates to a photovoltaic device comprising:

at least one photovoltaic cell comprising active thin films deposited on a substrate, said active films not being segmented; and

at least one static converter associated with each photovoltaic cell, in which:

each photovoltaic cell supplies electrical power with a maximum current and a nominal voltage; and

each static converter is able to transmit the electrical power supplied by the photovoltaic cell to a load, by decreasing the transmitted current and increasing the transmitted voltage.

According to the embodiments, the static converter is a DC/DC converter and/or a DC/AC converter.

According to one embodiment, the static converter is associated with control electronics able to control the decrease in the transmitted current and the increase in the transmitted voltage. The control electronics associated with the static converter may comprise a maximum power point tracker (MPPT). The control electronics may communicate with the load.

According to one embodiment, the device comprises a plurality of static converters arranged in series between each photovoltaic cell and the load.

According to one embodiment, the device comprises a single photovoltaic cell. The active films of the photovoltaic cell may cover more than 95% of the area of the substrate.

According to another embodiment, the device comprises a plurality of photovoltaic cells connected in parallel to the load each by at least one static converter.

The invention also relates to a photovoltaic generator comprising a plurality of photovoltaic devices, according to the invention, connected in series and/or in parallel.

The invention also relates to a method for manufacturing a photovoltaic device comprising the steps consisting in:

manufacturing at least one photovoltaic cell by depositing thin films in succession on a substrate; and

connecting at least one static converter to the terminals of each cell,

the method comprising no step of segmenting the thin films creating a plurality of elementary photovoltaic cells in series.

Other features and advantages of the invention will become clear on reading the following description of embodiments of the invention, given by way of example and with reference to the annexed drawings, which show:

FIG. 1, described above, a diagram of the steps for manufacturing a photovoltaic-cell device according to the prior art;

FIG. 2, described above, a flow chart of the steps for manufacturing a photovoltaic-cell device according to the prior art;

FIG. 3, described above, a diagram of a photovoltaic-cell device according to the prior art;

FIG. 4, a diagram of a photovoltaic device according to the invention;

FIG. 5, a diagram illustrating the electrical analogy of a single photovoltaic cell covering the entire area of a device;

FIG. 6, a diagram illustrating the electrical analogy of a photovoltaic cell of reduced area relative to the cell of FIG. 4;

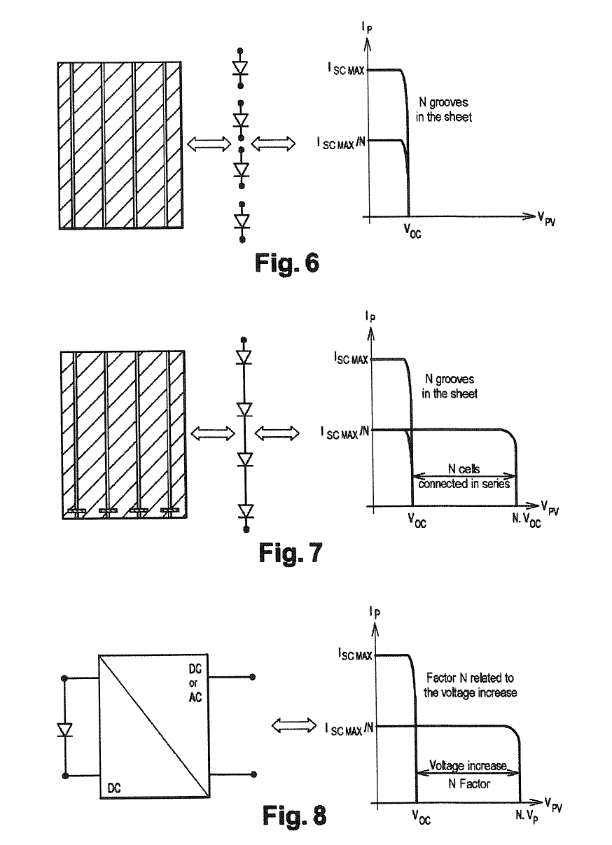

FIG. 7, a diagram illustrating the electrical analogy of a plurality of photovoltaic cells connected in series; and

FIG. 8, a diagram illustrating the electrical analogy of a photovoltaic device according to the invention.

The invention provides a thin-film photovoltaic device comprising at least one photovoltaic cell associated with at least one static converter. Each photovoltaic cell of the device according to the invention is electrically connected to a load by at least one static converter. The term “load” is understood to mean the electrical application that the photovoltaic device is intended to supply, independent of its nature (DC or AC).

The photovoltaic device according to the invention may comprise a single photovoltaic cell or a plurality of large cells, each associated with control electronics, and connected in parallel to the load. For a given panel, the laser segmentations are thus limited or even completely removed. The expression “large” photovoltaic cell is understood to mean a cell in which the active films are not segmented so that several elementary cells are connected in series. The manufacturing yield of the photovoltaic device is thus increased and dead regions are limited.

Such a “large” cell then supplies a high current, generally higher than required by the load, with a limited voltage, generally lower than required by the load. Each static converter is then designed to decrease the current supplied by the photovoltaic cell it is associated with by a factor N and to increase the voltage supplied to the load by at the most a factor N. The input power received by the converter, by the cell of the photovoltaic device, is substantially equal to the output power supplied by the converter to the load; the output power may be slightly lower than the input power because of thermal losses and losses in the converter (switching losses for example). The converter converts the energy received from the photovoltaic cell so as to match the output voltage to values compatible with the application of the load.

FIG. 4 illustrates a photovoltaic device according to the invention. In the rest of the description, the photovoltaic device according to the invention will be described with regard to a single photovoltaic cell. It will however be understood that the device described may be duplicated with a plurality of photovoltaic cells and static converters arranged in a module and connected in parallel to the load.

In FIG. 4, the device of the invention comprises a single photovoltaic cell 60. This single thin-film photovoltaic cell comprises a substrate 10, a first electrode 11, active films 15 forming at least one junction, and a second electrode 12. This photovoltaic cell 60 is manufactured using one of the methods described above except that the steps of segmenting the deposited films are excluded. The cell 60 of the device according to the invention comprises no segmentation grooves; i.e. its active films and electrodes are not segmented so as to form a plurality of elementary cells connected in series as is typically the case in the prior art. The active films 15 of the cell therefore cover almost all of the area of the substrate 10, more than about 95%. It is nevertheless possible to envision segmenting the cell so as to define its edges and set a maximum current.

The device of the invention furthermore comprises at least one static converter 50 connected across the terminals of the cell 60. Depending on the applications, the static converter 50 may be a DC/AC converter and/or a DC/DC converter. The static converter 50 is designed to transmit the electrical power supplied by the photovoltaic cell 60 to a load 100 of an external application—a battery, electricity or otherwise grid. The converter 50 of the device according to the invention is designed to decrease the transmitted current and increase the transmitted voltage.

FIG. 4 shows that a plurality of converters 50 may be arranged in series. The cell 60 supplies electrical power with a current dependent on sunlight and with a nominal voltage equal to the threshold voltage of the junction. A first converter may convert this power by decreasing the current by a first factor N and by increasing the voltage by at most a first factor N; a second converter may then convert this power by further decreasing the current by a second factor N′ and by further increasing the voltage by at most a factor N′. This cascade arrangement makes it possible to achieve high voltages with small converters.

Each converter 50 may be associated with control electronics which control the factor by which the current is decreased and the voltage increased. The control electronics may be common to all the converters of a cell. Such control electronics may also integrate maximum power point tracking (MPPT) control for the cell. The control electronics in particular make it possible to reprogram the operation of each converter 50, for example if the requirements of the load 100 change or if a better control algorithm becomes available. Such electronics may also detect operational faults, both with the cell 60 and with the converters 5, and stop power transmission and/or alert the load 100 and/or an external observer, such as a grid manager. The information is transmitted between the control electronics and the load 100 via power line communication (PLC) or by a radio link for example.

The control electronics of the converters 50 is not however essential to the implementation of the invention; if the voltage requirements of the load are fixed, the converter 50 may be specifically designed to supply a voltage within an operating range suited to the energy production capacity of the cell 60.

FIG. 5 (which does not form part of the invention but which is given for the purposes of comprehension) illustrates schematically the electrical analogy of a single photovoltaic cell covering the entire area of a device. As was explained above, a photovoltaic cell essentially consists of a diode; its output voltage therefore corresponds to the threshold voltage of the diode and the output current depends directly on the size of the cell and on the materials from which it is made and on environmental factors.

Such a cell can therefore supply a high maximum current I_{sc}, of about 150 A for example for active layers made of silicon thin films with an area of about 1 m², with a threshold voltage V_{oc} typically lower than 1 V. Such an output voltage is generally not compatible with the external loads for which the photovoltaic device is intended. For example, in a battery charging application, the required output voltage is about 12 V. Likewise, for a mains supply application, the output voltage required is about 240 V. These voltages are much higher than the voltages that can be supplied using a single photovoltaic cell covering the entire area of the device. Furthermore, few applications require a current as high as that supplied by a single large-area cell.

This is why the photovoltaic devices of the prior art comprise a plurality of cells connected in series. Each cell has a small size relative to the total area of the device; the output current is therefore decreased, but the series connection increases the output voltage.

FIG. 6 (which does not form part of the invention but which is given for the purposes of comprehension) illustrates schematically the electrical analogy of a cell of a segment of a photovoltaic device. If the photovoltaic device comprises N strips of cells occupying a whole area identical to that of the device of FIG. 5, then the maximum output current I_{sc} will be decreased by a factor N minus the area occupied by the grooves; the output voltage of the cell will still be equal to the threshold voltage of the diode forming the cell.

FIG. 7 (which does not form part of the invention but which is given for the purposes of comprehension) illustrates schematically the electrical analogy of a plurality of the elementary photovoltaic cells of FIG. 6 when connected in series. The maximum current I_{sc} remains decreased, due to the decreased area of each cell, but the output voltage is increased by a factor N because the elementary cells are connected in series. The output voltage may then be compatible with the external application.

Nevertheless, as discussed above, the segmentation of the films of the photovoltaic device is time-consuming, costly and forms a factor limiting production capacity. In addition, connecting the photovoltaic cells in series limits the output current of the device to the current of the cell that is the least well illuminated.

The invention therefore provides, as described with reference to FIG. 4, a photovoltaic device comprising a single photovoltaic cell 60 associated with at least one static converter 50.

FIG. 8 illustrates schematically the electrical analogy of a photovoltaic device according to the invention. As was described above, the photovoltaic cell of the device may be considered electrically analogous to a diode; its power characteristics will therefore be identical to that described with reference to FIG. 5, with a nominal output voltage Vₚ corresponding to the threshold voltage of the diode, and a maximum output current I_{sc} , that directly depends on the size of the cell and on the materials from which it is made and on environmental factors. The cell of the device according to the invention is however associated with a static (DC/DC or DC/AC) converter that converts the power supplied by the cell by decreasing the current by a factor N and by increasing the voltage by at most a factor N. The output power of the converter is substantially equal to the input power (power conversion does lead to losses even if the latter are limited) but the output voltage is possibly increased to values compatible with the requirements of the load.

The photovoltaic cell 60 of the device according to the invention thus supplies a high current I_{sc} which may reach 150 A, or even more, with a low nominal voltage Vₚ, typically lower than 1 V. The converter 50 of the device according to the invention increases this voltage by a factor N which may range between 10 and 50 depending on the application, with a corresponding decrease in current. If the voltage-increase/current-decrease factor needed to meet the requirements of the load 100 is high, several (DC/DC and/or DC/AC) converters 50 may be placed in cascade as illustrated in FIG. 4. Boost, Buck, Buck-boost or Cuck converters may be used in the context of the invention.

High currents can flow through the photovoltaic cell 60 of the device according to the invention without damaging the films of the cell. The materials of the films forming the electrodes 11, 12 and their thicknesses may be suitably chosen so that the electrodes have limited resistivity and heating. Likewise, the materials and cross sections of the electrical connection buses 31, 32 provided to collect current from each electrode 11, 12, of the cell, may be designed to conduct high currents.

Of course, the present invention is not limited to the embodiments described by way of example. In particular, the materials mentioned for manufacturing the various films of the cell were given merely by way of illustration and depend on the manufacturing processes and equipment used. Likewise, the current and voltage values were given merely by way of illustration and depend on the type of photovoltaic cell and on the load for which the device is intended.

1. A photovoltaic device comprising:
at least one photovoltaic cell comprising active thin films deposited on a substrate, said active films not being segmented; and
at least one static converter associated with each photovoltaic cell, in which:
each photovoltaic cell supplies electrical power with a maximum current (Icc) and a nominal voltage (Vp); and
each static converter is able to transmit the electrical power supplied by the photovoltaic cell to a load, by decreasing the transmitted current and increasing the transmitted voltage.

2. The photovoltaic device according to claim 1, in which the static converter is a DC/DC converter and/or a DC/AC converter.

3. The photovoltaic device according to claim 1, in which the static converter is associated with control electronics able to control the decrease in the transmitted current and the increase in the transmitted voltage.

4. The photovoltaic device according to claim 3, in which the control electronics associated with the static converter comprise a maximum power point tracker (MPPT).

5. The photovoltaic device according to claim 3, in which the control electronics is able to communicate with the load.

6. The photovoltaic device according to claim 1, comprising a plurality of static converters arranged in series between each photovoltaic cell and the load.

7. The photovoltaic device according to claim 1, comprising a single photovoltaic cell.

8. The photovoltaic device of claim 7, in which the active films of the photovoltaic cell cover more than 95% of the area of the substrate.

9. The photovoltaic device according to claim 1, comprising a plurality of photovoltaic cells connected in parallel to the load each by at least one static converter.

10. A photovoltaic generator comprising a plurality of photovoltaic devices, according to claim 1, each of said photovoltaic devices connected in series and/or in parallel.

11. A method for manufacturing a photovoltaic device comprising:
manufacturing at least one photovoltaic cell by depositing thin films in succession on a substrate;
creating a plurality of elementary photovoltaic cells in series without segmenting the thin films
providing terminals on each of the at least one photovoltaic cells: and
connecting at least one static converter to the terminals of each photovoltaic cell.

12. A photovoltaic device configured to provide power to a load, comprising:
(a) a photovoltaic cell having first and second terminals, said photovoltaic cell comprising:
a substrate having first and second opposing surfaces; and
a plurality of un-segmented active thin films deposited on a first one of the first and second surfaces of said substrate wherein said photovoltaic cell is configured to provide electrical power having a maximum current and a nominal voltage; and
(b) a static converter coupled across the first and second terminals of said photovoltaic cell, wherein said static converter is configured to decrease transmitted current and increase transmitted voltage supplied by said photovoltaic cell such that the photovoltaic device can supply power to the load.

13. The photovoltaic device of claim 12 wherein said static converter is a first one of a plurality of serially coupled static converters and wherein each of said plurality of static converters is configured to decrease transmitted current and increase transmitted voltage so as to supply power to the load.

14. The photovoltaic device of claim 12 wherein:
said photovoltaic cell is a first one of a plurality of photovoltaic cells; and
said static converter is a first one of a like plurality of static converters, each of said plurality of static converters electrically coupled to a corresponding one said plurality of photovoltaic cells.

15. The photovoltaic device of claim 14 wherein each of said plurality of photovoltaic cells and static converters are coupled in parallel to the load.

16. The photovoltaic device of claim 13 wherein at least one of said static converters is provided as a DC/DC converter.

17. The photovoltaic device of claim 13 wherein at least one of said static converters is provided as a DC/AC converter.

18. The photovoltaic device of claim 12 further comprising a controller coupled to said static converter to control the decrease in transmitted current and the increase in transmitted voltage.

19. The photovoltaic device of claim 17 wherein said controller comprises a maximum power point tracker (MPPT).

20. The photovoltaic device of claim 13 further comprising a plurality of controllers each of said controllers coupled to a corresponding one of said plurality of static converters each of said controllers configured to control the decrease in transmitted current and the increase in transmitted voltage provided by the corresponding static converter.
